(19) United States
(12) Patent Application Publication
(10) Pub. No.: US 2017/0140810 A1
(43) Pub. Date: May 18, 2017

(54) MEMORY DEVICE AND MEMORY SYSTEM INCLUDING THE SAME FOR CONTROLLING COLLISION BETWEEN ACCESS OPERATION AND REFRESH OPERATION

(71) Applicant: Samsung Electronics Co., Ltd., Suwon-si (KR)

(72) Inventors: Won-Jun CHOI, Yongin-si (KR); Hui-Kap YANG, Hwaseong-si (KR)

(21) Appl. No.: 15/340,345

(22) Filed: Nov. 1, 2016

(30) Foreign Application Priority Data
Nov. 17, 2015 (KR) 10-2015-0161154

(51) Int. Cl. G11C 11/406; G11C 7/10; G11C 11/4096; G11C 11/408; G11C 11/4091

(52) U.S. Cl. CPC G11C 11/40615; G11C 11/4087; G11C 11/4091; G11C 11/4096; G11C 7/1072

(57) ABSTRACT

A memory device includes a memory bank, a command control logic circuit, a row selection circuit, a refresh controller and a collision controller. The memory bank includes a plurality of memory blocks. The command control logic circuit decodes commands received from a memory controller to generate control signals. The command control logic receives an active command for an access operation during a refresh operation. The row selection circuit performs the access operation and the refresh operation with respect to the memory bank. The refresh controller controls the refresh operation. The collision controller generates a wait signal causing a delay of the access operation based on a result of a comparison of a row address associated with the access operation and a refresh address associated with the refresh operation.

### CROSS-REFERENCE TO RELATED APPLICATION

This U.S. Non-provisional application claims priority under 35 USC §119 to Korean Patent Application No. 10-2015-0161154, filed on Nov. 17, 2015, in the Korean Intellectual Property Office (KIPO), the disclosure of which is incorporated by reference in its entirety herein.

### BACKGROUND

1. Technical Field

Example embodiments relate generally to semiconductor integrated circuits, and more particularly to a memory device and a memory system including the memory device for controlling collision between an access operation and a refresh operation.

2. Discussion of the Related Art

Semiconductor memory devices for storing data may be classified into volatile memory devices and non-volatile memory devices. Volatile memory devices, such as dynamic random access memory (DRAM) devices, are typically configured to store data by charging or discharging capacitors in memory cells, and lose the stored data when power is off. Non-volatile memory devices, such as flash memory devices, may maintain stored data even though power is off. Volatile memory devices are widely used as main memories of various apparatuses, while non-volatile memory devices are widely used for storing program code and/or data in various electronic devices, such as computers, mobile devices, etc.

In the volatile memory devices, cell charges stored in a memory cell may be lost by a leakage current. In addition, when a wordline is transitioned frequently between an active state and a precharged state, that is, when the wordline is accessed intensively or frequently, the affected memory cell connected to the adjacent wordline may lose the stored charges. The charges of the memory cell have to be recharged before the data are lost by the leakage of the cell charges. Such recharge of the cell charges is referred to as a refresh operation and the refresh operation has to be performed repeatedly before the cell charges are lost significantly. In the memory device requiring high speed of an access operation including a read operation and a write operation, the time for refresh may become a major factor in decreasing performance of the memory device.

### SUMMARY

At least one example embodiment of the present disclosure may provide a memory device for controlling collision between an access operation and a refresh operation.

At least one example embodiment of the present disclosure may provide a memory system including a memory device for controlling collision between an access operation and a refresh operation.

According to example embodiments, a memory device includes: a memory bank including a plurality of memory blocks; a command control logic circuit configured to decode commands received from a memory controller to generate control signals, the command control logic circuit configured to receive an active command for an access operation during a refresh operation; a row selection circuit configured to perform the access operation and the refresh operation with respect to the memory bank; a refresh controller configured to control the refresh operation; and a collision controller configured to generate a wait signal causing a delay of the access operation based on a result of a comparison of a row address associated with the access operation and a refresh address associated with the refresh operation.

According to example embodiments, a memory system includes a memory device and a memory controller configured to control the memory device. The memory device includes a memory bank including a plurality of memory blocks, a command control logic circuit configured to decode commands received from the memory controller to generate control signals, the command control logic circuit configured to receive an active command for an access operation during a refresh operation, a row selection circuit configured to perform the access operation and the refresh operation with respect to the memory bank, a refresh controller configured to control the refresh operation and a collision controller configured to generate a wait signal indicating collision between the access operation and the refresh operation based on a result of comparing a row address associated with the access operation and a counter address associated with the refresh operation.

According to example embodiments, a memory device includes: a memory bank including a plurality of memory blocks; a logic circuit configured to decode commands received from a memory controller, the logic circuit configured to receive an active command for an access operation during a refresh operation; a row selection circuit configured to perform the access operation and the refresh operation with respect to the memory bank; a first controller configured to control the refresh operation; and a second controller configured to compare a row address for the access operation and a counter address for the refresh operation and generate a comparison result, the second controller configured to activate a wait signal to delay the access operation when the comparison result indicates that a memory block corresponding to the row address is equal to or adjacent to a memory block corresponding to the counter address.

The memory device and the memory system according to example embodiments may transfer the active command for the access operation during the refresh operation by controlling collision between the access operation and the refresh operation. The access operation may be initiated before the refresh operation is completed and the operation speed and the performance of the memory device and the memory system may be enhanced.

### BRIEF DESCRIPTION OF THE DRAWINGS

Example embodiments of the present disclosure will be more clearly understood from the following detailed description taken in conjunction with the accompanying drawings.

FIG. 1 is a diagram illustrating a command transfer according to example embodiments.

FIG. 2 is a block diagram illustrating a memory system according to example embodiments.

FIG. 3 is a block diagram illustrating a memory device included in the memory system of FIG. 2 according to example embodiments.

FIG. 4 is a block diagram illustrating an example embodiment of a collision controller included in the memory device of FIG. 3.

FIG. 5 is a block diagram illustrating an example embodiment of a bank row selection circuit included in the memory device of FIG. 3.

FIG. 6 is a block diagram illustrating an example embodiment of a memory bank included in the memory device of FIG. 3.

FIGS. 7 and 8 are timing diagrams illustrating operations of a memory system according to example embodiments.

FIG. 9 is a flow chart illustrating a method of operating a memory device according to example embodiments.

FIG. 10 is a diagram illustrating operation modes of a memory device according to example embodiments.

FIGS. 11 and 12 are timing diagrams illustrating operations of a memory system according to example embodiments.

FIG. 13A is a diagram illustrating example commands used in a memory system according to example embodiments.

FIG. 13B is a diagram illustrating a mode register including auto self-refresh exit information according to example embodiments.

FIG. 14 is a block diagram illustrating a memory module according to example embodiments.

FIG. 15 is a diagram illustrating a structure of a stacked memory device according to example embodiments.

FIG. 16 is a block diagram illustrating a memory system according to example embodiments.

FIG. 17 is a block diagram illustrating a mobile system according to example embodiments.

FIG. 18 is a block diagram illustrating a computing system according to example embodiments.

### DETAILED DESCRIPTION OF THE EMBODIMENTS

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the sizes and relative sizes of layers and regions may be exaggerated for clarity. Like numerals refer to like elements throughout. It will be understood that, although the terms first, second, third etc. may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

As is traditional in the field of the inventive concepts, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

Unless otherwise defined, all terms (including technical and scientific terms) used herein have the same meaning as commonly understood by one of ordinary skill in the art to which this disclosure belongs.

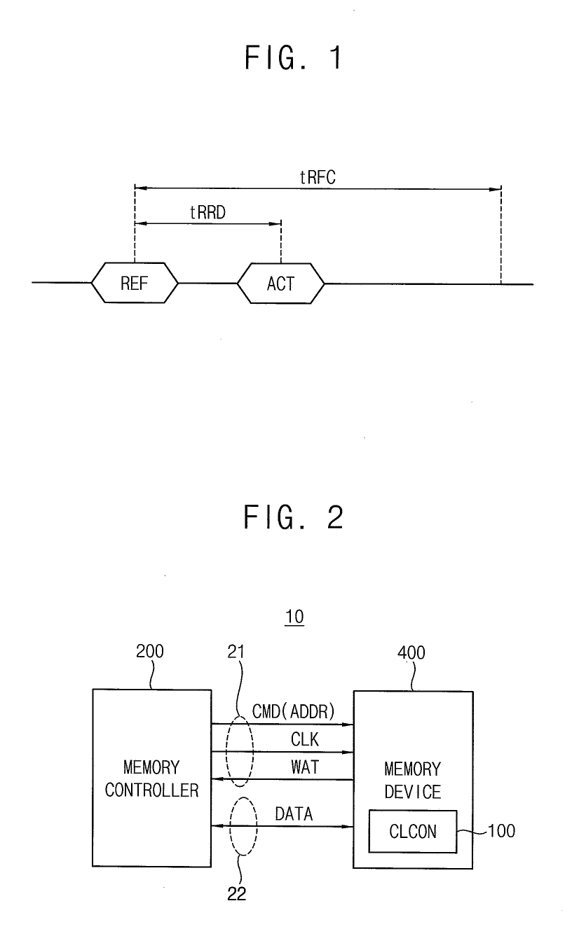

FIG. 1 is a diagram illustrating a command transfer according to example embodiments.

Referring to FIG. 1, an active command ACT may be transferred from a memory controller to a memory device before a refresh cycle time tRFC is elapsed from a time point when a refresh command REF is transferred. As used herein, a memory device may refer to a semiconductor device may refer to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

For example, DRAM may perform the refresh operation periodically due to charge leakage of memory cells storing data. According to scale down of the manufacturing process of the DRAM, the storage capacitance of the memory cell may be decreased and the refresh period may be shortened. The refresh period may be further shortened because the entire refresh time is increased as the memory capacity of the DRAM is increased. In general, a host, such as the memory controller, may not access the DRAM while the DRAM is in the refresh operation because of possible collision between the refresh operation and the access operation, and may adversely affect the performance of the memory system.

For example, in case of 8 Gb DDR4 (double data rate 4) DRAM, an average refresh interval time tREFi is about 7.8 μs (microsecond) and the refresh cycle time tRFC is about 350 ns (nanosecond). In other words, the memory controller has to issue the refresh command per 7.8 μs and the memory controller may access the DRAM after waiting 350 ns from issuance of the refresh command. As a result, the memory controller consumes 4.5% time (350 ns/7.8 μs) for the refresh operation and such time loss degrades performance of the memory system.

The memory device according to example embodiments may control the collision between the refresh operation and the access operation. For example, in some embodiments, the memory controller may transmit an active command ACT to the memory controller without a restriction of the refresh cycle time tRFC. The minimum time interval between the time points of transferring the refresh command REF and the active command ACT may be set to a predetermined delay time shorter than the refresh cycle time tRFC. For example, as illustrated in FIG. 1, the minimum time interval between the time points of transferring the refresh command REF and the active command ACT may be set to a row active-to-row active time tRRD between different memory banks. In this examplary embodiment, the row active-to-row active time tRRD may be set to about 10 ns, but is not limited thereto.

As such, the memory device and the memory system according to example embodiments may transfer the active command for the access operation during the refresh operation by controlling collision between the access operation and the refresh operation. The access operation may be initiated before the refresh operation is completed and the operation speed and the performance of the memory device and the memory system may be enhanced.

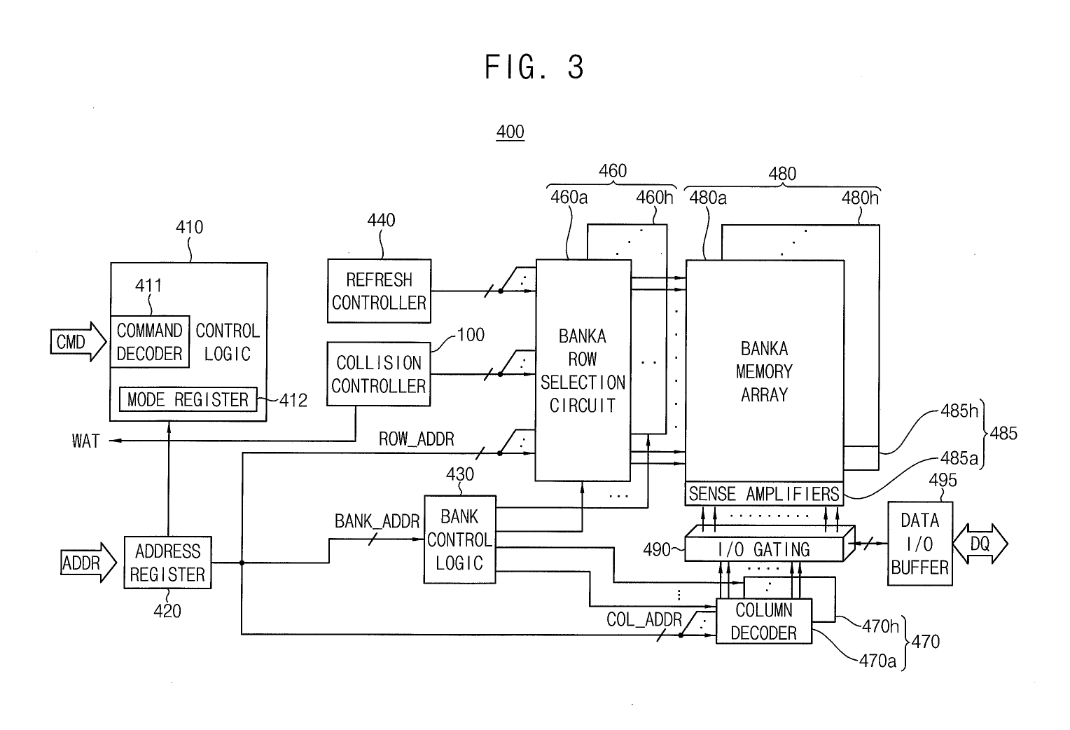

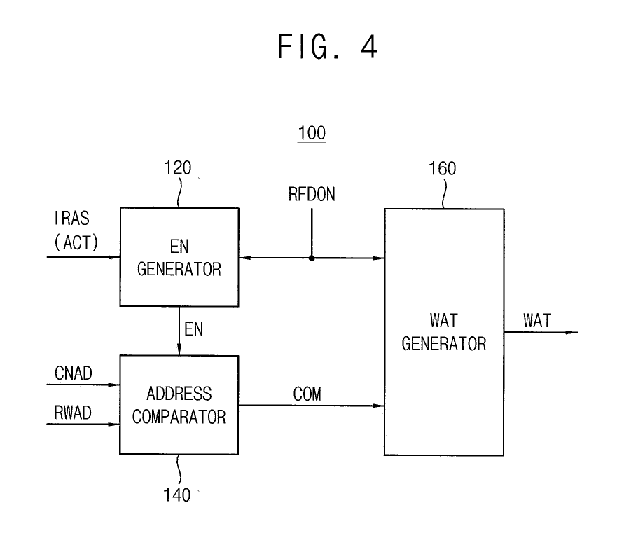

FIG. 2 is a block diagram illustrating a memory system according to example embodiments, and FIG. 3 is a block diagram illustrating a memory device included in the memory system of FIG. 2 according to example embodiments.

Referring to FIG. 2, a memory system 10 includes a memory controller 200 and a memory device 400. The memory controller 200 and the memory device 400 include respective interfaces for mutual communication. The interfaces may be connected through a control bus 21 for transferring a command CMD, an address ADDR, a clock signal CLK, a wait signal WAT, etc. and a data bus 22 for transferring data. According to some standards for memory devices, the address ADDR may be incorporated in the command CMD. The memory controller 200 may generate the command CMD to control the memory device 400 and the data may be written in or read from the memory device 400 under the control of the memory controller 200.

According to example embodiments, the memory controller 200 may transfer the active command to the memory device 400 without the restriction of the refresh cycle time tRFC. For example, the memory controller 200 may transfer the active command to the memory device 400 prior to completion of the refresh cycle time tRFC, i.e., prior to completion of a refresh operation. The memory device 400 may include a collision controller 100 configured to control a collision between a refresh operation and an active operation. The collision controller 100 may generate a wait signal WAT indicating the access operation, if performed immediately, may cause a collision between the access operation and the refresh operation, which is fed back to the memory controller 200. The memory controller 200 may, based on the wait signal WAT, adjust command schedule such as retransfer of the active command ACT, delay of the write command WR and the read command RD, etc. as will be described below.

Referring to FIG. 3, in some embodiments, the memory device 400 may include a command control logic 410 (e.g., a command control logic circuit), an address register 420, a bank control logic 430 (e.g., a bank control logic circuit), a row selection circuit 460, a column decoder 470, a memory cell array 480, a sense amplifier unit 485 (e.g., a group or bank of sense amplifierss), an input/output (I/O) gating circuit 490, a data input/output (I/O) buffer 495, a refresh controller 440 and a collision controller 100.

The memory cell array 480 may include a plurality of bank arrays 480a˜480h. The row selection circuit 460 may include a plurality of bank row selection circuits 460a˜460h respectively coupled to the bank arrays 480a˜480h, the column decoder 470 may include a plurality of bank column decoders 470a˜470h respectively coupled to the bank arrays 480a˜480h, and the sense amplifier unit 485 may include a plurality of bank sense amplifiers 485a˜485h respectively coupled to the bank arrays 480a˜480h.

The address register 420 may receive an address ADDR including a bank address BANK_ADDR, a row address ROW_ADDR and a column address COL_ADDR from the memory controller 200 (as shown in FIG. 2). The address register 420 may provide the received bank address BANK_ADDR to the bank control logic 430, may provide the received row address ROW_ADDR to the row selection circuit 460, and may provide the received column address COL_ADDR to the column decoder 470.

The bank control logic 430 may generate bank control signals in response to the bank address BANK_ADDR. One of the bank row selection circuits 460a˜460h corresponding to the bank address BANK_ADDR may be activated in response to the bank control signals, and one of the bank column decoders 470a˜470h corresponding to the bank address BANK_ADDR may be activated in response to the bank control signals.

The row address ROW_ADDR from the address register 420 may be applied to the bank row selection circuits 460a˜460h. The activated one of the bank row selection circuits 460a˜460h may decode the row address RA, and may activate a word-line corresponding to the row address RA. For example, the activated bank row selection circuit may apply a word-line driving voltage to the word-line corresponding to the row address RA.

The column decoder 470 may include a column address latch. The column address latch may receive the column address COL_ADDR from the address register 420, and may temporarily store the received column address COL_ADDR. In some embodiments, in a burst mode, the column address latch 450 may generate column addresses that increment from the received column address COL_ADDR. The column address latch 450 may apply the temporarily stored or generated column address to the bank column decoders 470a˜470h.

The activated one of the bank column decoders 470a˜470h may decode the column address COL_ADDR and may control the input/output gating circuit 490 in order to output data corresponding to the column address COL_ADDR.

In some embodiments, the I/O gating circuit 490 may include a circuitry for gating input/output data. The I/O gating circuit 490 may further include read data latches for storing data that is output from the bank arrays 480a˜480h, and write drivers for writing data to the bank arrays 480a˜480h.

Data to be read from one bank array of the bank arrays 480a˜480h may be sensed by a sense amplifier 485 coupled to the one bank array from which the data is to be read, and may be stored in the read data latches. The data stored in the read data latches may be provided to the memory controller 200 (as shown in FIG. 2) via the data I/O buffer 495. Data DQ to be written in one bank array of the bank arrays 480a˜480h may be provided to the data I/O buffer 495 from the memory controller 200. The write driver may write the data DQ in one bank array of the bank arrays 480a˜480h.

The command control logic 410 may control operations of the memory device 400. For example, the command control logic 410 may generate control signals for the memory device 400 in order to perform a write operation or a read operation. The command control logic 410 may include a command decoder 411 that decodes a command CMD received from the memory controller 200 and a mode register 412 that sets an operation mode of the memory device 400.

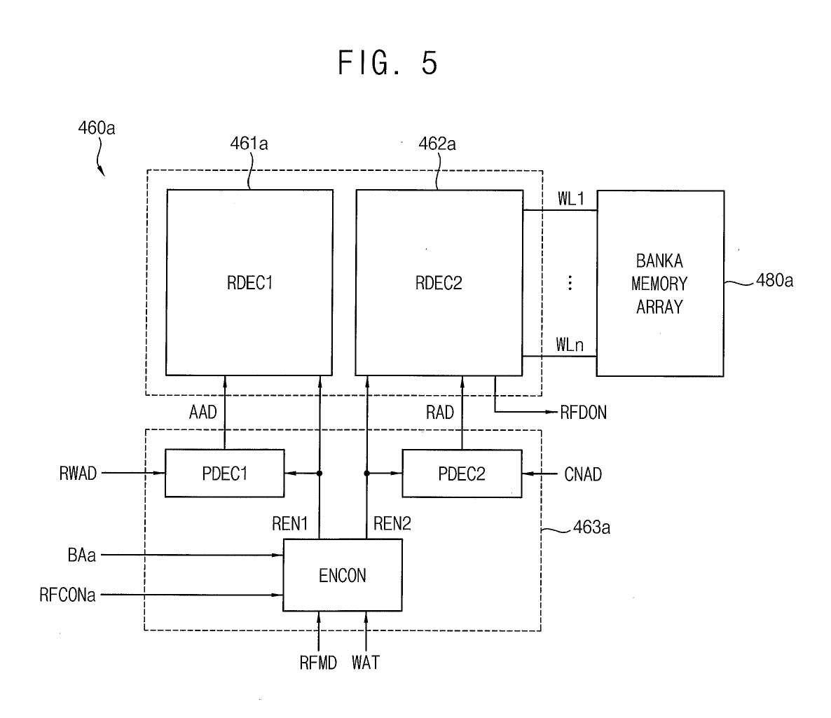

Although, in this exemplary embodiment, FIG. 3 illustrates the command control logic 410 and the address register 420 that are distinct from each other, the command control logic 410 and the address register 420 may be implemented as a single inseparable circuit in other embodiments. In addition, although, in this exemplary embodiment, FIG. 4 illustrates the command CMD and the address ADDR are provided as distinct signals, the command CMD and the address ADDR may be provided as a combined signals as specified by the Low Power Double Data Rate 5 (LPDDR5) standards in other embodiments.

The refresh controller 440 may generate signals for controlling the refresh operation of the memory device 400. For example, the refresh controller 440 may include an address counter (not shown) configured to generate a counter address signal that is increased or decreased sequentially. The refresh controller 440 may operate selectively in an access mode or in a self-refresh mode in response to a refresh mode signal from the command control logic 410. The refresh controller 440 may control the row selection circuit 460 such that a normal refresh operation or an auto refresh operation may be performed in response to the refresh command from the memory controller 200 in the access mode and a self-refresh operation may be performed in response to at least one clock signal in the self-refresh mode. Hereinafter, the refresh operation is considered as including the normal refresh operation in the access mode and the self-refresh operation in the self-refresh mode.

According to this exemplary embodiment, the collision controller 100 may generate the wait signal WAT indicating whether collision occurs between the access operation and the refresh operation based on a result of comparing a row address signal for the access operation and a counter address signal for the refresh operation. The wait signal WAT may be fed back to the memory controller 200 in FIG. 2.

FIG. 4 is a block diagram illustrating an example embodiment of a collision controller included in the memory device of FIG. 3.

Referring to FIG. 4, a collision controller 100 may include an enable signal generator 120, an address comparator 140 and a wait signal generator 160.

The enable signal generator 120 may generate an enable signal EN based on an internal signal IRAS indicating reception timing of the active command ACT and a refresh done signal RFDON indicating completion of the refresh operation. The command control logic 410 in FIG. 3 may activate the internal signal IRAS in response to the active command ACT received from the memory controller 200. The internal signal IRAS may be an internal RAS (row address strobe) signal indicating start timing of row access for enabling a row or a wordline corresponding to a row address. The refresh done signal RFDON may be provided from the row selection circuit 460 in FIG. 3. The refresh done signal RFDON may be in logic low level (e.g., the refresh done signal RFDON may be deactivated) or in logic high level (e.g., the refresh done signal RFDON may be activated) during the refresh cycle time tRFC to indicate a start and an end time points of the refresh operation. For example, the refresh done signal RFDON is in logic low level during the refresh cycle time tRFC to indicate the start time point of the refresh operation and the refresh done signal RFDON is in logic high level during the refresh cycle time tRFC to indicate the end time point of the refresh operation.

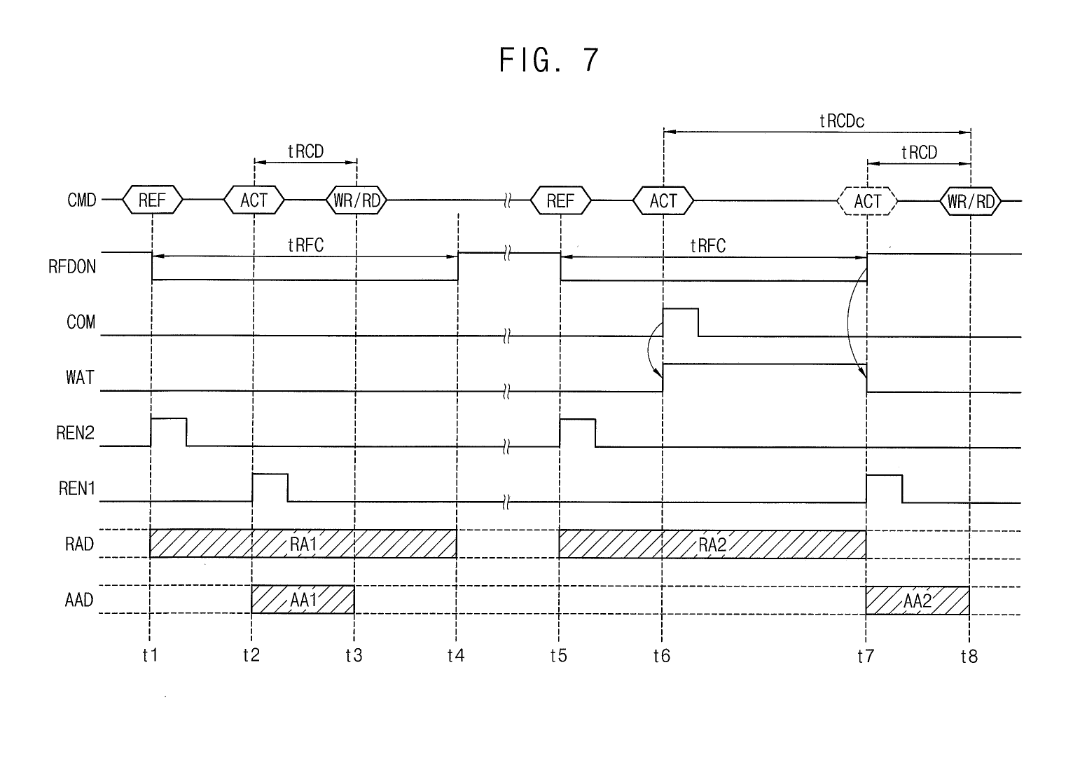

The address comparator 140 may generate a comparison signal COM based on the enable signal EN, a row address signal RWAD for the access operation and a counter address signal CNAD for the refresh operation. As will be described below with reference to FIG. 6, the address comparator 140 may activate the comparison signal COM when the memory block corresponding to the row address signal RWAD shares a write-read circuit such as a sense amplifier with the memory block corresponding to the counter address signal CNAD.

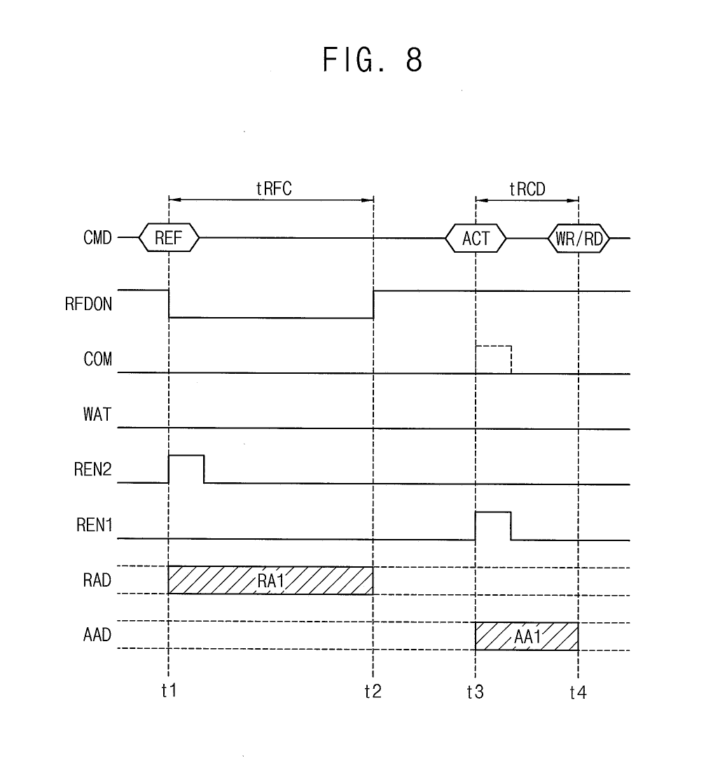

The wait signal generator 160 may generate the wait signal WAT based on the comparison signal COM and the refresh done signal RFDON. As will be described below with reference to FIGS. 7, 11 and 12, the wait signal generator 160 may activate the wait signal WAT in response to the comparison signal COM and deactivate the wait signal WAT in response to the refresh done signal RFDON.

The enable signal generator 120 may activate the enable signal EN when the active command ACT is received during the refresh operation and the address comparator 140 may be enabled when the enable signal EN is activated. In other words, the address comparator 140 may be disabled when the enable signal EN is deactivated, e.g., when no active command ACT is received by the enable signal generator 120 during the refresh operation. If the address comparator 140 is disabled, the comparison signal COM may be deactivated regardless of the comparison result of the addresses.

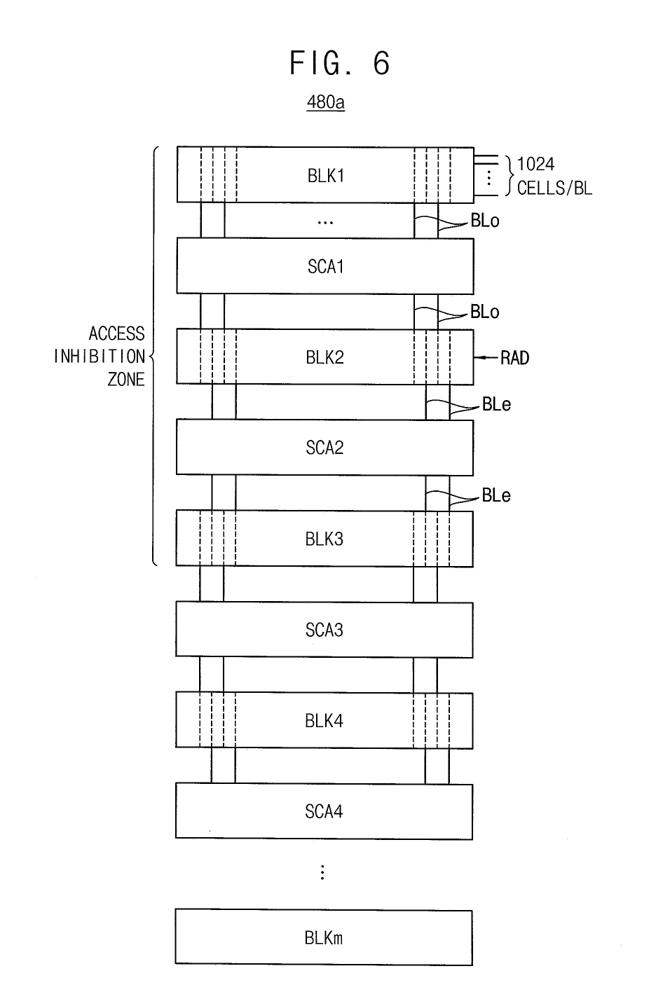

FIG. 5 is a block diagram illustrating an example embodiment of a bank row selection circuit included in the memory device of FIG. 3. Even though the configuration and the operation of the first bank row selection circuit 460a are described with reference to FIG. 5, the other bank row selection circuits 460b˜460h in FIG. 3 can be understood similarly. For convenience of description, the bank memory array or the memory bank 480a is illustrated together in FIG. 5.

Referring to FIG. 5, the bank row selection circuit 460a may include a first row decoder RDEC1 461a, a second row decoder RDEC2 462a and a decoder control block 463a.

The first row decoder 461a may select, among the wordlines WL1˜WLn, one wordline corresponding to an access address signal AAD in response to the access address signal AAD and a first row enable signal REN1. The second row decode 462a may select, among the wordlines WL1˜WLn, one wordline corresponding to a refresh address signal RAD in response to the refresh address signal RAD and a second row enable signal REN2. In addition, the second decoder 462a may generate the refresh done signal RFDON in FIG. 5, which is activated whenever the refresh operation with respect to the refresh address signal RAD is completed.

The decoder control block 463a may include an enable controller ENCON, a first predecoder PDEC1 and a second predecoder PDEC2.

The enable controller ENCON may generate the first row enable signal REN1 and the second row enable signal REN2 based on a bank control signal BAa, a refresh control signal RFCONa (e.g., a self-refresh control signal), a refresh mode signal RFMD and a wait signal WAT. The first predecoder PDEC1 may generate the access address signal AAD based on a row address signal RWAD and the first row enable signal REN1. The second predecoder PDEC2a may generate the refresh address signal RAD based on a counter address signal CNAD and the second row enable signal REN2. The counter address signal CNAD may be provided from an address counter that is included in the refresh controller 440 in FIG. 3.

A first logic level (e.g., a logic low level) of the refresh mode signal RFMD may indicate the access mode and a second logic level (e.g., a logic high level) of the refresh mode signal RFMD may indicate the self-refresh mode.

In the access mode, when the corresponding bank control signal BAa is activated, the enable controller ENCON may activate the first row enable signal REN1 and the first row decoder 461a may select and enable the wordline corresponding to the access address signal AAD in response to the activated first row enable signal REN1. While the wait signal WAT is activated, the enable controller ENCON may deactivate the first row enable signal REN1 even when the bank control signal BAa is activated.

Also in the access mode, the enable controller ENCON may selectively activate the second row enable signal REN2 in response to the activated bank control signal BAa. When the second row enable signal REN2 is activated, the second decoder 462a may select and enable the wordline corresponding to the refresh address signal RAD. When the refresh operation is completed with respect to the enabled wordline, the second row decoder 462a may activate the refresh done signal RFDON.

In the self-refresh mode, the enable controller ENCON may activate the second row enable signal REN2a periodically in response to the self-refresh signal RFCONa. Also in the self-refresh mode, the enable controller ENCON may activate the first row enable signal REN1a when the corresponding bank control signal BAa is activated while the wait signal WAT is deactivated. When the first row enable signal REN1 is activated, the first decoder 461a may select and enable the wordline corresponding to the access address signal AAD. While the wait signal WAT is activated, the enable controller ENCON may deactivate the first row enable signal REN1 even when the bank control signal BAa is activated.

Although, in this exemplary embodiment, the first row decoder 461a and the second row decoder 462a are separated in FIG. 5, the first and second row decoders 461a and 462b may be integrated into a single row decoder in other example embodiments. For example, the single row decoder may adopt time-division multiplexing to receive the access address signal ADD in advance and then receive the refresh address signal RAD.

FIG. 6 is a block diagram illustrating an example embodiment of a memory bank included in the memory device of FIG. 3.

Referring to FIG. 6, a memory bank 480a may include a plurality of memory blocks BLK1˜BLKm. The sense amplifier unit 485 in FIG. 3 may include a plurality of sense amplifier circuits SAC1˜SAC4 that are distributed in the memory bank 480a. Four sense amplifiers SAC1˜SAC4 are illustrated in FIG. 3 for convience, but the disclosure is not limited to four sense amplifiers. In some embodiments, the sense amplifier unit 485 in FIG. 3 may include more than four sense amplifers, e.g., SAC1˜SAC(m−1) that are distributed in the memory bank 480a. Each of the memory blocks BLK1˜BLKm may include a predetermined number of wordlines. For example, each of the memory blocks BLK1˜BLKm may include 1024 memory cells per bitline.

As illustrated in FIG. 6, each of the sense amplifier circuits SAC1˜SAC4 may be connected to the two adjacent memory blocks disposed at the top and bottom sides. For example, each of the sense amplifier circuits SAC1˜SAC4 may be connected to only the odd-numbered bitlines of the top-side memory block and bottom-side memory block or only the even-numbered bitlines of the top-side memory block and the bottom-side memory block.

In this exemplary structure, if the wordline in the one memory block is selected and enabled for the refresh operation, the wordlines in the one memory block and the two adjacent memory blocks cannot be selected and enabled simultaneously for the access operation. For example, when the wordline corresponding to the refresh address signal RAD in the second memory block BLK2 is selected for the refresh operation, the other wordlines in the first, second and third memory blocks BLK1, BLK2 and BLK3 cannot be selected simultaneously for the access operation. As such, the wordlines or the rows, which cannot be selected for the access operation simultaneously with the refresh operation, may be referred to as an access inhibition zone.

In this exemplary embodiment, the collision controller 100 in FIG. 4 may compare the row address signal RWAD and the counter address signal CNAD and may activate the wait signal WAT if the row address signal RWAD is included in the access inhibition zone. For example, if the memory bank has a structure as illustrated in FIG. 6, the collision controller 100 may activate the wait signal WAT when the memory block corresponding to the row address signal RWAD is equal to or adjacent to the memory block corresponding to the counter address signal CNAD.

As such, the bank row selection circuit 460a may enable a row corresponding to the refresh address signal RAD in the refresh memory block among the plurality of memory blocks BLK1˜BLKm and selectively enable or disable a row corresponding to the access address siganl AAD in the access memory block among the plurality of memory blocks BLK1˜BLKm in response to the wait signal WAT.

FIGS. 7 and 8 are timing diagrams illustrating operations of a memory system according to example embodiments.

Referring to FIGS. 1 through 7, at time point t1, the memory device 400 receives the refresh command REF from the memory controller 200. The enable controller ENCON activates the second row enable signal REN2 and the bank row selection circuit 460a starts the refresh operation with respect to the row RA1 indicated by the refresh address signal RAD. The refresh done signal RFDON is deactivated (e.g., in the logic low level) to indicate the start of the refresh operation.

At time point t2 before the refresh cycle time tRFC is elapsed from time point t1, the memory device 400 receives the active command ACT from the memory controller 200. The collision controller 100 determines absence of collision between the refresh operation and the access operation (e.g., the collision controller 100 determines, based on a result of comparing the row address signal RWAD and the counter address signal CNAD, that the memory block corresponding to the row address signal RWAD is neither equal nor adjacent to the memory block corresponding to the counter address signal CNAD) and maintains the deactivated states of the comparison signal COM and the wait signal WAT. The enable controller ENCON activates the first row enable signal REN1 and the bank row selection circuit 460a starts the access operation with respect to the row AA1 indicated by the access address signal AAD.

At time point t3 after the RAS-to-CAS delay time tRCD is elapsed from time point t2, the memory device 400 receives the write command WR or the read command RD from the memory controller 200 and performs the write operation or the read operation with respect to the received column address.

At time point t4 after the refresh cycle time tRFC is elapsed from time point t1, the refresh done signal RFDON is activated (e.g., in the logic high level) to indicate the end of the refresh operation.

As such, when the collision between the active operation and the refresh operation does not occur, the refresh operation for the one row RA1 and the access operation for another row AA1 may be performed simultaneously.

At time point t5, the memory device 400 receives the refresh command REF from the memory controller 200. The enable controller ENCON activates the second row enable signal REN2 and the bank row selection circuit 460a starts the refresh operation with respect to the row RA2 indicated by the refresh address signal RAD. The refresh done signal RFDON is deactivated (e.g., in the logic low level) to indicate the start of the refresh operation.

At time point t6 before the refresh cycle time tRFC is elapsed from time point t5, the memory device 400 receives the active command ACT from the memory controller 200. The collision controller 100 determines occurrence of collision between the refresh operation and the access operation (e.g., the collision controller 100 determines, based on a result of comparing the row address signal RWAD and the counter address signal CNAD, that the memory block corresponding to the row address signal RWAD is equal to or adjacent to the memory block corresponding to the counter address signal CNAD) and activates the comparison signal COM and the wait signal WAT. The enable controller ENCON deactivates the first row enable signal REN1 and the bank row selection circuit 460a does not start the access operation with respect to the row AA2 indicated by the access address signal AAD.

At time point t7 after the refresh cycle time tRFC is elapsed from time point t5, the refresh done signal RFDON is activated (e.g., in the logic high level) to indicate the end of the refresh operation. The collision controller 100 deactivates the wait signal WAT in response to the activation of the refresh done signal RFDON. The memory controller 200 determines the end of the refresh operation at time point t7 when the wait signal WAT is deactivated and resumes the delayed access operation with respect to the row AA2.

At time point t8, after the RAS-to-CAS delay time tRCD is elapsed from time point t7, the memory device 400 receives the write command WR or the read command RD from the memory controller 200 and performs the write operation or the read operation with respect to the received column address.

In some example embodiments, if the wait signal WAT is activated to indicate the occurrence of collision between the refresh operation and the access operation, the memory controller 200 may not retransfer the active command ACT to the memory device 400 and transfer the write command WR or the read command RD at time point t8 after the RAS-to-CAS delay time tRCD is elapsed from time point t7 when the wait signal WAT is deactivated. In this case, the bank row selection circuit 460a may delay the access operation by the activation time interval t6˜t7 of the wait signal WAT. Although the active command ACT is not retransferred from the memory controller 200 at time point t7, the first predecoder PDEC1 in the bank row selection circuit 460a may latch and keep the row address signal RWAD, which is provided at time point t6 with the active command ACT, and the first predecoder PDEC1 may provide the access address signal AAD to the first row decoder 461a at time point t7.

In other example embodiments, if the wait signal WAT is activated to indicate the occurrence of collision between the refresh operation and the access operation, the memory controller 200 may retransfer the active command ACT to the memory device 400 at time point t7 when the wait signal WAT is deactivated and transfer the write command WR or the read command RD at time point t8 after the RAS-to-CAS delay time tRCD is elapsed from time point t7. In this case, the bank row selection circuit 460a may resume the access operation based on the retransferred row address signal RWAD, which is provided at time point t7 with the retransferred active command ACT.

As such, if there is collision between the refresh operation and the access operation, the access operation may be delayed by the activation time interval t6˜t7 of the wait signal WAT, that is, until the refresh operation is completed. As a result, the RAS-to-CAS delay time tRCDc when the collision occurs between the access operation and the refresh operation may be increased by the activation time interval t6˜t7 of the wait signal WAT in comparison with the RAS-to-CAS delay time tRCD when the collision does not occur between the access operation and the refresh operation.

FIG. 8 illustrates a case that the active command ACT is received while the refresh operation is not performed in accordance with some example embodiments.

Referring to FIGS. 1 through 6 and 8, at time point t1, the memory device 400 receives the refresh command REF from the memory controller 200. The enable controller ENCON activates the second row enable signal REN2 and the bank row selection circuit 460a starts the refresh operation with respect to the row RA1 indicated by the refresh address signal RAD. The refresh done signal RFDON is deactivated (e.g., in the logic low level) to indicate the start of the refresh operation.

At time point t2 after the refresh cycle time tRFC is elapsed from time point t1, the refresh done signal RFDON is activated (e.g., in the logic high level) to indicate the end of the refresh operation.

At time point t3 when the refresh operation is not performed, the memory device 400 receives the active command ACT from the memory controller 200. The collision controller 100 determines absence of collision between the refresh operation and the access operation and maintains the deactivated states of the comparison signal COM and the wait signal WAT. The enable controller ENCON activates the first row enable signal REN1 and the bank row selection circuit 460a starts the access operation with respect to the row AA1 indicated by the access address signal AAD.

At time point t4 after the RAS-to-CAS delay time tRCD is elapsed from time point t3, the memory device 400 receives the write command WR or the read command RD from the memory controller 200 and performs the write operation or the read operation with respect to the received column address.

As such, if the active command ACT is received while the refresh operation is not performed, the refresh operation for the one row RA1 and the access operation for another row AA1 may be performed sequentially.

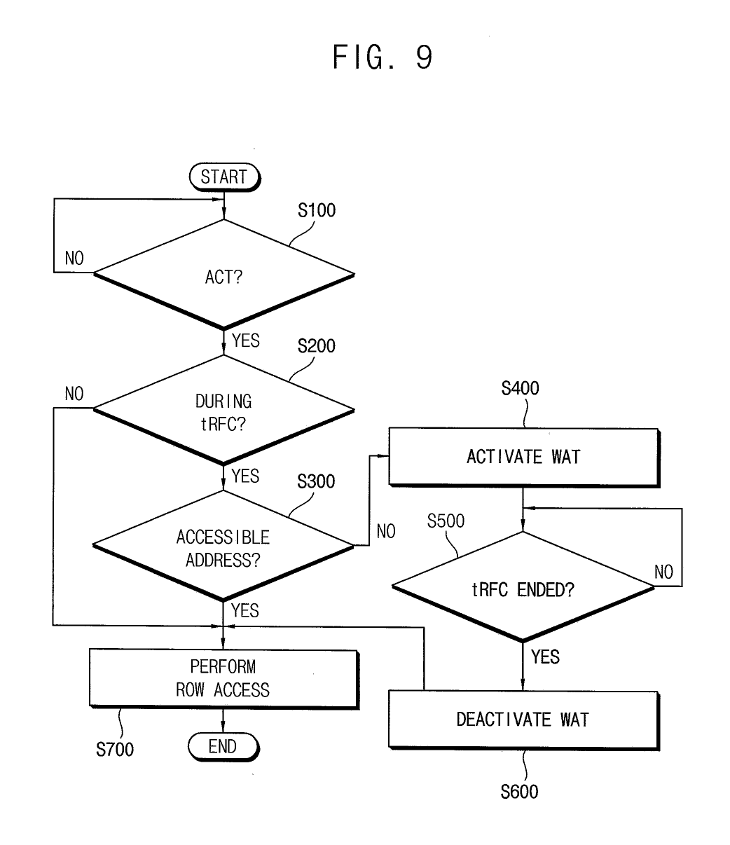

FIG. 9 is a flow chart illustrating a method of operating a memory device according to example embodiments.

Referring to FIGS. 1 through 9, the command control logic 410 may monitor whether the active command ACT is received (S100). When the active command ACT is received (S100: YES), the collision controller 100 may determine whether the active command ACT is received during the refresh operation, that is, during the refresh cycle time tRFC (S200). For example, the enable signal generator 120 in the collision controller 100 may generate the enable signal EN based on the internal signal IRAS indicating reception timing of the active command ACT and the refresh done signal RFDON indicating completion of the refresh operation. The activation of the enable signal EN may indicate that the active command ACT is received during the refresh operation and the deactivation of the enable signal EN may indicate that the active command ACT is received while the refresh operation is not performed.

When the active command ACT is received while the refresh operation is not performed (S200: NO), the collision controller 100 may not activate the wait signal WAT and the bank row selection signal 460a may perform row access by enabling the wordline corresponding to the row address (S700).

When the active command ACT is received while the refresh operation is performed (S200: YES), the collision controller 100 determines whether the row address accompanied with the active command ACT is accessible S300. For example, the address comparator 140 in the collision controller 100 may generate the comparison signal COM based on the enable signal EN, the row address signal RWAD for the access operation and the counter address signal CNAD for the refresh operation. The activation of the comparison signal COM may indicate that the row address is not accessible by the collision between the refresh operation and the access operation and the deactivation of the comparison signal COM may indicate that the row address is accessible because there is no collision between the refresh operation and the access operation.

When the row address is accessible (S300: YES), the collision controller 100 may not activate the wait signal WAT and the bank row selection signal 460a may perform row access by enabling the wordline corresponding to the row address (S700).

When the row address is not accessible (S300: NO), the collision controller 100 may activate the wait signal WAT (S400) and the bank row selection signal 460a may delay the row access.

The collision controller 100 monitors whether the refresh operation is completed, that is, the refresh cycle time tRFC is elapsed or ended (S500). When the refresh cycle time tRFC is ended (S500: YES), the collision controller 100 deactivates the wait signal WAT (S600) and the bank row selection signal 460a may resumes the delayed row access (S700).

The address comparator 140 may activate the comparison signal COM when the memory block corresponding to the row address signal RWAD shares a write-read circuit such as a sense amplifier with the memory block corresponding to the counter address signal CNAD.

As such, the method of operation the memory device according to example embodiments may perform the access operation simultaneously during the refresh operation by controlling collision between the access operation and the refresh operation. The access operation may be initiated before the refresh operation is completed and the operation speed and the performance of the memory device and the memory system may be enhanced.

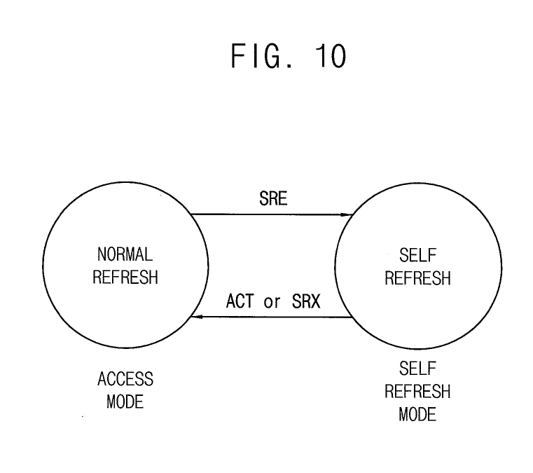

FIG. 10 is a diagram illustrating operation modes of a memory device according to example embodiments.

Referring to FIG. 10, the memory device according to example embodiments may operate selectively in an access mode or in a self-refresh mode. The refresh controller 440 in FIG. 3 may switch between the access mode and the self-refresh mode in response to the refresh mode signal RFMD provided from the command control logic 410. The refresh controller 440 may control the row selection circuit 460 such that a normal refresh operation or an auto refresh operation may be performed in response to the refresh command from the memory controller 200 in the access mode and a self-refresh operation may be performed in response to at least one clock signal in the self-refresh mode.

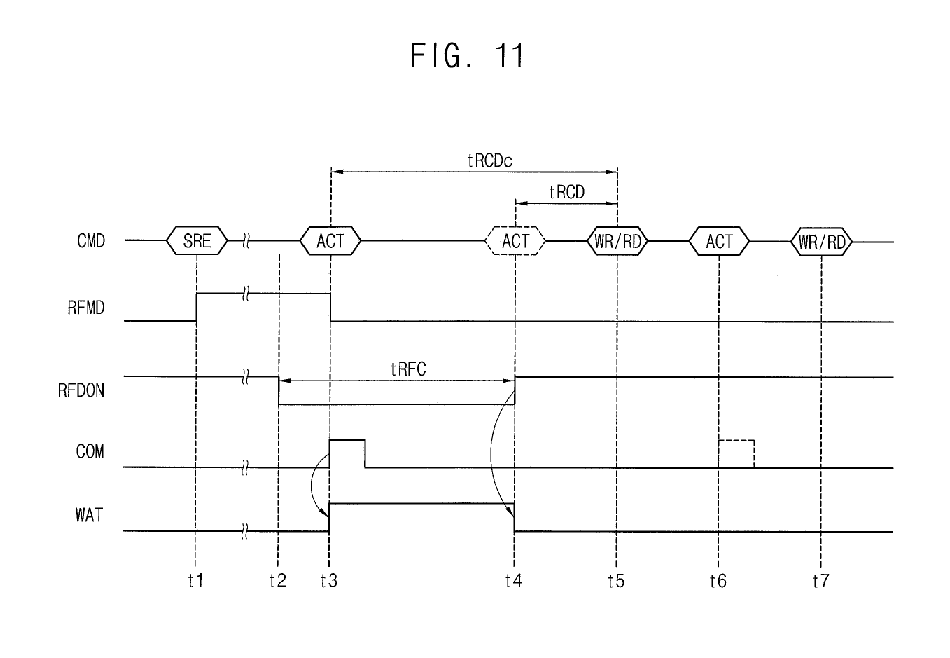

The memory device 400 may change the operation mode from the access mode to the self-refresh mode in response to the self-refresh entry command SRE from the memory controller 200. In addition, the memory device 400 may change the operation mode from the self-refresh mode to the access mode in response to the self-refresh exit command SRX or the active command ACT from the memory controller 200 as will be described below with reference to FIGS. 11 and 12.

FIGS. 11 and 12 are timing diagrams illustrating operations of a memory system according to example embodiments.

FIGS. 11 and 12 illustrate examples that the logic high level of the refresh mode signal RFMD indicates the self-refresh mode and the logic low level of the refresh mode signal RFMD indicates the access mode. FIG. 11 illustrates an example that the operation mode is changed from the self-refresh mode to the access mode in response to the active command ACT and FIG. 12 illustrates an example that the operation mode is changed from the self-refresh mode to the access mode in response to the self-refresh exit command SRX.

Referring to FIGS. 1 through 6 and 11, at time point t1, the memory device 400 receives the self-refresh entry command SRE from the memory controller 200. The command control logic 410 activates the refresh mode signal RFMD (e.g., in the logic high level) in response to the self-refresh entry command SRE to indicate the self-refresh mode. The memory device 400 may perform the refresh operation in the self-refresh mode periodically in response to an internal clock signal.

For example, at time point t2, the refresh operation may start and the refresh done signal RFDON may be deactivated (e.g., in the logic low level) to indicate the start of the refresh operation.

At time point t3 before the refresh cycle time tRFC is elapsed from time point t2, the memory device 400 receives the refresh command REF from the memory controller 200. The collision controller 100 determines occurrence of collision between the refresh operation and the access operation and activates the comparison signal COM and the wait signal WAT. As described with reference to FIG. 7, the enable controller ENCON deactivates the first row enable signal REN1 and the bank row selection circuit 460a does not start the access operation with respect to the row indicated by the access address signal AAD.

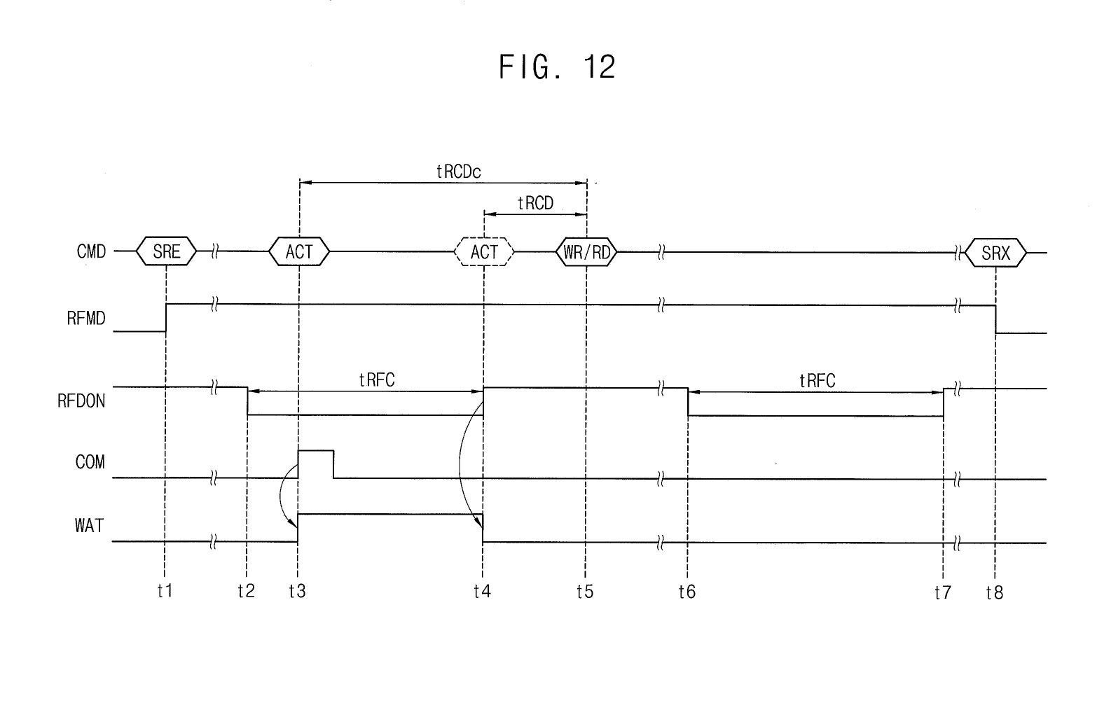

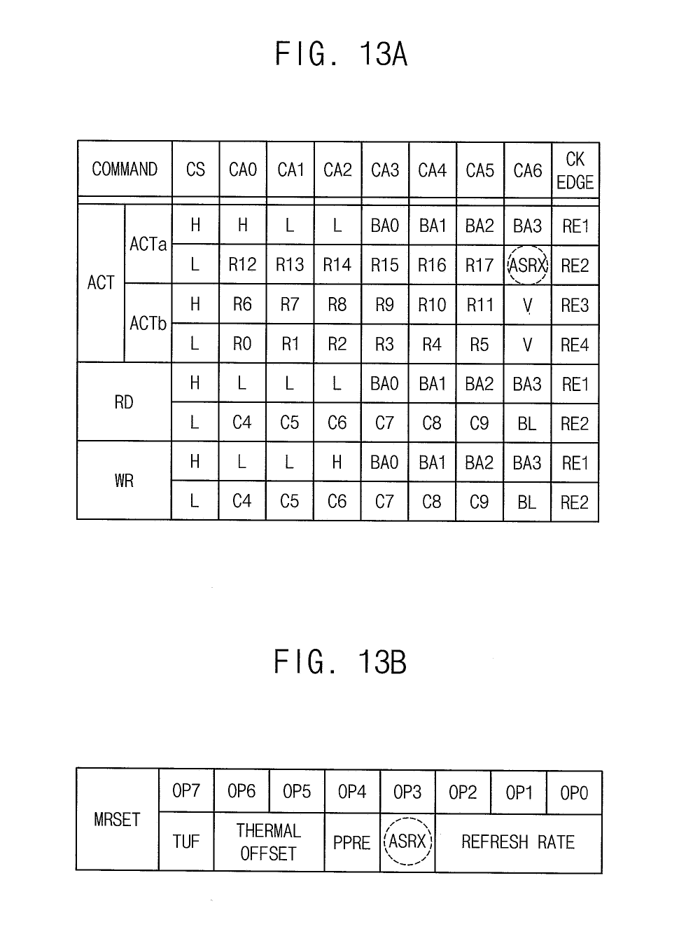

At time point t3, the command control logic 410 deactivates the refresh mode signal RFMD (e.g., in the logic low level) in response to the active command ACT to indicate the access mode. The command control logic 410 may determine the end of the self-refresh mode at time point t3 based on the auto self-refresh exit information as will be described below with reference to FIGS. 13A and 13B.

At time point t4 after the refresh cycle time tRFC is elapsed from time point t2, the refresh done signal RFDON is activated (e.g., in the logic high level) to indicate the end of the refresh operation. The collision controller 100 deactivates the wait signal WAT in response to the deactivation of the refresh done signal RFDON. As described with reference to FIG. 7, the memory controller 200 determines the end of the refresh operation at time point t7 when the wait signal WAT is deactivated and resumes the delayed access operation with respect to the row indicated by the access address signal.

At time point t5, after the RAS-to-CAS delay time tRCD is elapsed from time point t4, the memory device 400 receives the write command WR or the read command RD from the memory controller 200 and performs the write operation or the read operation with respect to the received column address.

In some example embodiments, if the wait signal WAT is activated to indicate the occurrence of collision between the refresh operation and the access operation, the memory controller 200 may not retransfer the active command ACT to the memory device 400 and transfer the write command WR or the read command RD at time point t5 after the RAS-to-CAS delay time tRCD is elapsed from time point t4 when the wait signal WAT is deactivated. In this case, the bank row selection circuit 460a may delay the access operation by the activation time interval t3˜t4 of the wait signal WAT. Although the active command ACT is not retransferred from the memory controller 200 at time point t4, the first predecoder PDEC1 in the bank row selection circuit 460a may latch and keep the row address signal RWAD, which is provided at time point t3 with the active command ACT, and the first predecoder PDEC1 may provide the access address signal AAD to the first row decoder 461a at time point t4.

In other example embodiments, if the wait signal WAT is activated to indicate the occurrence of collision between the refresh operation and the access operation, the memory controller 200 may retransfer the active command ACT to the memory device 400 at time point t4 when the wait signal WAT is deactivated and transfer the write command WR or the read command RD at time point t5 after the RAS-to-CAS delay time tRCD is elapsed from time point t4. In this case, the bank row selection circuit 460a may resume the access operation based on the retransferred row address signal RWAD, which is provided at time point t4 with the retransferred active command ACT.

As such, if there is collision between the refresh operation and the access operation, the access operation may be delayed by the activation time interval t3˜t4 of the wait signal WAT, that is, until the refresh operation is completed. As a result, the RAS-to-CAS delay time tRCDc when the collision occurs between the access operation and the refresh operation may be increased by the activation time interval t3˜t4 of the wait signal WAT in comparison with the RAS-to-CAS delay time tRCD when the collision does not occur between the access operation and the refresh operation.

At time point t6 during the access mode, the memory device 400 receives another active command ACT from the memory controller 200. The collision controller 100 determines absence of collision between the refresh operation and the access operation and maintains the deactivated states of the comparison signal COM and the wait signal WAT. At time point t7 after the RAS-to-CAS delay time tRCD is elapsed from time point t6, the memory device 400 receives the write command WR or the read command RD from the memory controller 200 and performs the write operation or the read operation with respect to the received column address.

If the command control logic 410 determines the maintenance of the self-refresh mode at time point t3 based on the auto self-refresh exit information, the self-refresh mode may be maintained until time point t6. In this case, the command control logic 410 may determine the end of the self-refresh mode at time point t6 again based on the auto self-refresh exit information

The operation illustrated in FIG. 12 is similar to that of FIG. 11 and the repeated descriptions are omitted.

Referring to FIG. 12, at time point t3, the command control logic 410 determines to maintain the self-refresh mode based on the auto self-refresh exit information and the refresh mode signal RFMD may maintain the logic high level at time point t3. As known through the refresh done signal RFDON, the refresh operation in the self-refresh mode may be performed without the refresh command from the memory controller 200. The memory device 400 may receive the active command ACT after time point t3, and the command control logic 410 may determine the end or the maintenance of the self-refresh mode whenever the active command ACT is received. FIG. 12 illustrates an example that the command control logic 410 determines the maintenance of the self-refresh mode repeatedly.

At time point t8, the memory device 400 receives the self-refresh exit command SRX from the memory controller 200. The command control logic 410 may deactivate the refresh mode signal RFMD (e.g., in the logic low level) in response to the self-refresh exit command SRX to indicate the access mode.

FIG. 13A is a diagram illustrating example commands used in a memory system according to example embodiments.

FIG. 13A illustrates example combinations of the chip selection signal CS and the command-address signals CA0˜CA6 representing an active command ACT, a read command RD and a write command WR. H indicates the logic high level, L indicates the logic low level, R0˜R17 indicate bits of a row address, BA0˜BA3 indicate bits of a bank address, V indicates any one of the logic low level and the logic high level, BL indicates a burst length, C4˜C9 indicate bits of a column address, and RE1˜RE4 indicate first through fourth rising edges of a clock signal CK.

The active command ACT may include a first portion ACTa and a second portion ACTb and the active command ACT may be transferred during a plurality of clock cycles, for example, during the four clock cycles as illustrated in FIG. 13A. The active command ACT may include the bank address bits BA0˜BA3 and the row address bits R0˜R17. Also the active command ACT may include the auto self-refresh exit information ASRX. The command control logic 410 may determine whether to exit the self-refresh mode based on the auto self-refresh exit information ASRX included in the active command ACT. The command control logic 410 may finish the self-refresh mode in response to the active command ACT when the auto self-refresh exit information ASRX has a first value (e.g., the logic low value L), and the command control logic 410 may maintain the self-refresh mode regardless of the active command ACT when the auto self-refresh exit information ASRX has a second value (e.g., the logic high value H).

Each of the read command RD and the write command WR may include the bank address bits BA0˜BA3 and the column address bits C4˜C9 and may be transferred during a plurality of clock cycles, for example, during the two clock cycles as illustrated in FIG. 13A.

FIG. 13A illustrates non-limiting examples of combinations of the chip selection signal CS and the command-address signals CA0˜CA6. In at least one embodiment, combinations of the signals representing the commands may be changed in various ways.

FIG. 13B is a diagram illustrating a mode register including auto self-refresh exit information.

For example, the associated mode register in the mode register set 412 in FIG. 3 may include a setting configuration MRSET as illustrated in FIG. 13B. The operand values OP0˜OP7 may include refresh rate information, auto self-refresh exit information ASRX, post-package repair entry/exit information PPRE, thermal offset information and temperature update flag TUF.

In this exemplary embodiment, the command control logic 410 may determine whether to exit the self-refresh mode based on the auto self-refresh exit information ASRX when the active command ACT is received during the self-refresh mode. The command control logic refers to the setting configuration MRSET in the mode register at time point of receiving the active command ACT. The command control logic 410 may exit the self-refresh mode in response to the active command ACT if the auto self-refresh exit information ASRX has a first value (e.g., the logic low value) and maintain the self-refresh mode even though the active command ACT is received if the auto self-refresh exit information ASRX has a second value (e.g., the logic high value).

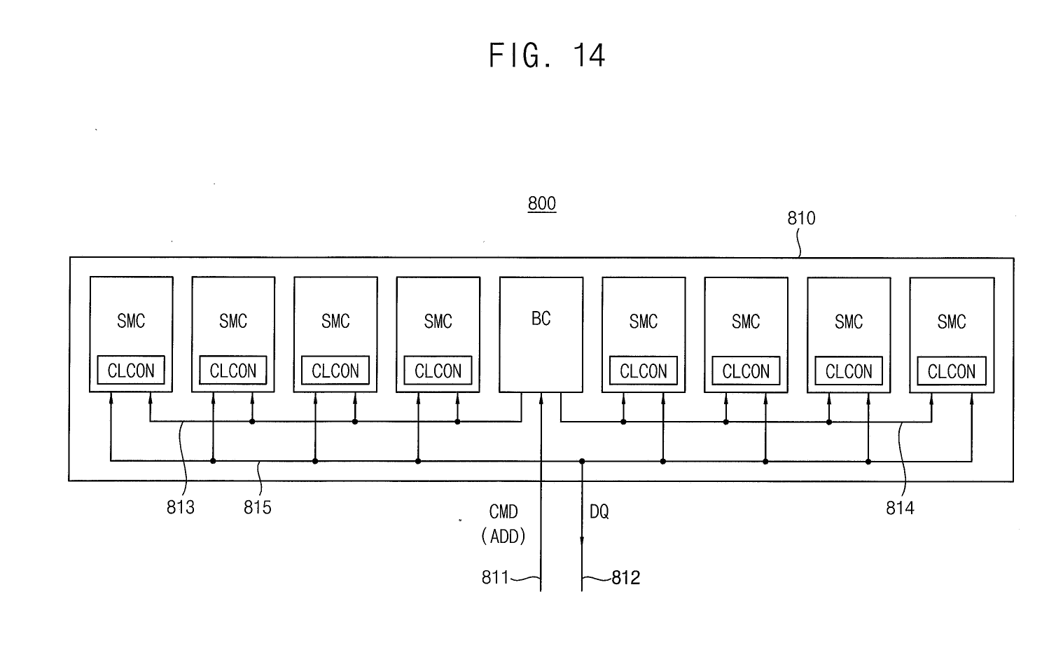

FIG. 14 is a block diagram illustrating a memory module according to example embodiments.

Referring to FIG. 14, a memory module 800 may include a module substrate 810, a plurality of semiconductor memory chips SMC and a buffer chip BC.

The semiconductor memory chips SMC may be mounted on the module substrate 810 and each of the semiconductor memory chips SMC may receive data DQ from an external device such as a memory controller through a data bus 812 in a write mode, or transmit the data DQ to the external device through the data bus 812 in a read mode.

The buffer chip BC may be mounted on the module substrate 810 and the buffer chip BC may receive command signals CMD and address signals ADD through a control bus 511 to provide the received signals CMD and ADD to the semiconductor memory chips SMC through internal buses 513 and 514. The buffer chip BC may include a register to store control information of the memory module 800.

The semiconductor memory chips SMC may include respective collision controllers CLCON as described with reference to FIGS. 1 through 13. Using the collision controllers CLCON, the semiconductor memory chips SMC may receive the active command during the refresh operation by controlling collision between the access operation and the refresh operation. The access operation may be initiated before the refresh operation is completed and the operation speed and the performance of the memory device and the memory system may be enhanced.

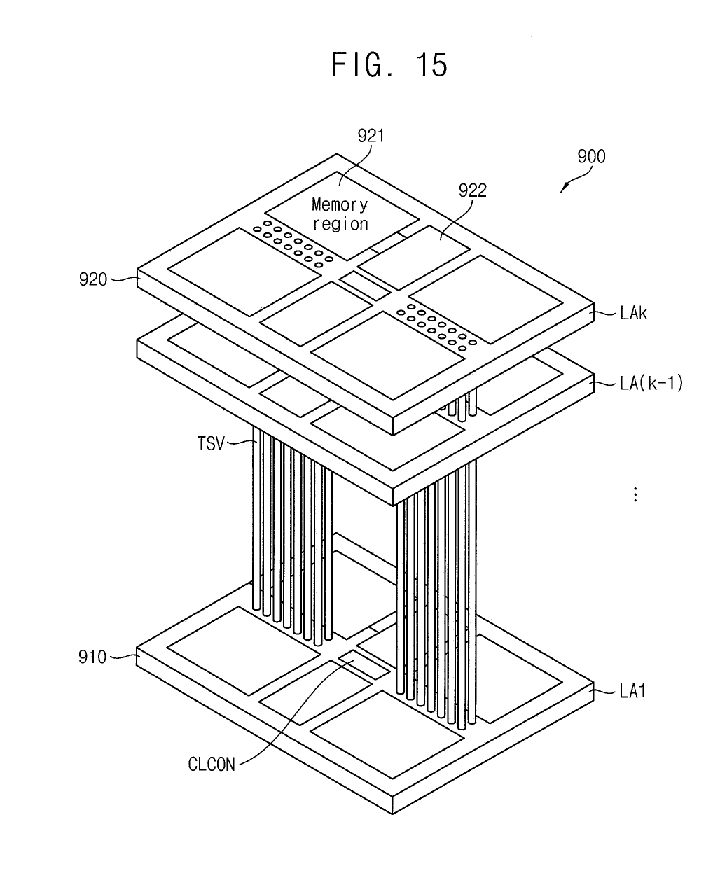

FIG. 15 is a diagram illustrating a structure of a stacked memory device according to example embodiments.

Referring to FIG. 15, a semiconductor memory device 900 may include first through kth semiconductor integrated circuit layers LA1 through LAk, in which the lowest first semiconductor integrated circuit layer LA1 may be a master layer and the other semiconductor integrated circuit layers LA2 through LAk may be slave layers.

The first through kth semiconductor integrated circuit layers LA1 through LAk may transmit and receive signals between the layers by through-substrate vias (e.g., through-silicon vias TSVs). The lowest first semiconductor integrated circuit layer LA1 as the master layer may communicate with an external memory controller through a conductive structure formed on an external surface.

The first semiconductor integrated circuit layer 910 through the kth semiconductor integrated circuit layer 920 may include memory regions 921 and various peripheral circuits 922 for driving the memory regions 921. For example, the peripheral circuits may include a row (X)-driver for driving wordlines of a memory, a column (Y)-driver for driving bit lines of the memory, a data input/output unit for controlling input/output of data, a command buffer for receiving a command from outside and buffering the command, and an address buffer for receiving an address from outside and buffering the address.

The first semiconductor integrated circuit layer 910 may further include a control logic and the control logic may generate control signals to control the memory region 921 based on the command-address signals from the memory controller 200 as described in refernce to FIG. 2.

According to example embodiments, the first semiconductor integrated circuit layer 910 may include a collision controller CLCON as described with reference to FIGS. 1 through 13. Using the collision controller CLCON, the first semiconductor integrated circuit layer 910 may receive the active command during the refresh operation by controlling collision between the access operation and the refresh operation. The access operation may be initiated before the refresh operation is completed and the operation speed and the performance of the memory device and the memory system may be enhanced.

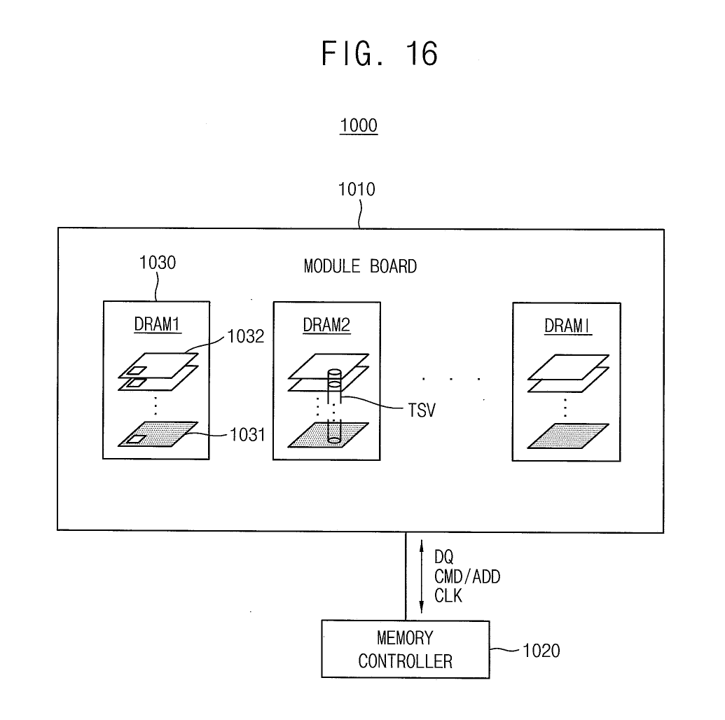

FIG. 16 is a block diagram illustrating a memory system according to example embodiments.

Referring to FIG. 16, a memory system 1000 may include a memory module 1010 and a memory controller 1020. The memory module 1010 may include at least one semiconductor memory device 1030 mounted on a module substrate. For example, the semiconductor memory device 1030 may be constructed as a DRAM chip. In addition, the semiconductor memory device 1030 may include a stack of semiconductor dies. In some example embodiments, the semiconductor dies may include the master die 1031 and the slave dies 1032. Signal transfer between the semiconductor chips may occur via through-substrate vias (e.g., through-silicon vias TSV) and/or bonding wires.

The memory module 1010 may communicate with the memory controller 1020 via a system bus. Data DQ, a command/address CMD/ADD, and a clock signal CLK may be transmitted and received between the memory module 1010 and the memory controller 1020 via the system bus.

In this exemplary embodiment, the semiconductor memory device 1030 may include a collision controller CLCON as described with reference to FIGS. 1 through 13. Using the collision controller CLCON, the semiconductor memory device 1030 may receive the active command during the refresh operation by controlling collision between the access operation and the refresh operation. The access operation may be initiated before the refresh operation is completed and the operation speed and the performance of the memory device and the memory system may be enhanced.

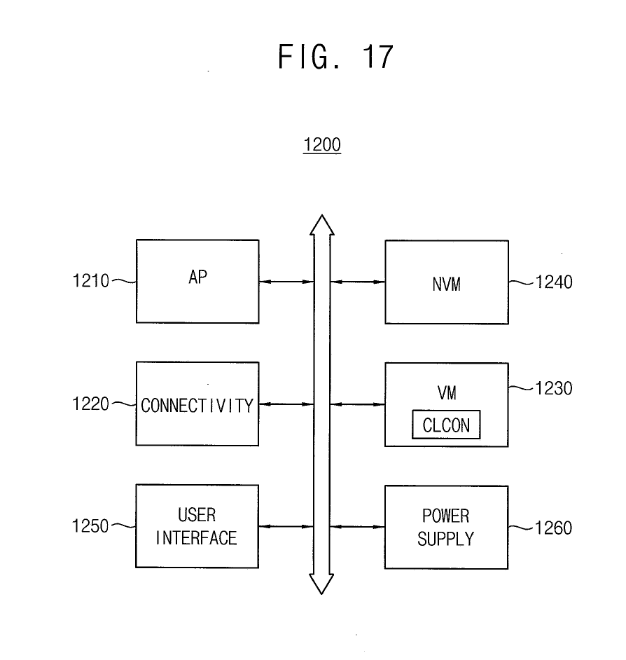

FIG. 17 is a block diagram illustrating a mobile system according to example embodiments.

Referring to FIG. 17, a mobile system 1200 includes an application processor 1210, a connectivity unit 1220, a volatile memory device (VM) 1230, a nonvolatile memory device 1240, a user interface 1250, and a power supply 1260. In some embodiments, the mobile system 1200 may be a mobile phone, a smart phone, a personal digital assistant (PDA), a portable multimedia player (PMP), a digital camera, a music player, a portable game console, a navigation system, or another type of electronic device.

The application processor 1210 may execute applications such as a web browser, a game application, a video player, etc. In some embodiments, the application processor 1210 may include a single core or multiple cores. For example, the application processor 1210 may be a multi-core processor such as a dual-core processor, a quad-core processor, a hexa-core processor, etc. The application processor 1210 may include an internal or external cache memory.

The connectivity unit 1220 may perform wired or wireless communication with an external device. For example, the connectivity unit 1220 may perform Ethernet communication, near field communication (NFC), radio frequency identification (RFID) communication, mobile telecommunication, memory card communication, universal serial bus (USB) communication, etc. In some embodiments, connectivity unit 1220 may include a baseband chipset that supports communications, such as global system for mobile communications (GSM), general packet radio service (GPRS), wideband code division multiple access (WCDMA), high speed downlink/uplink packet access (HSxPA), etc.

The volatile memory device 1230 may store data processed by the application processor 1210, or may operate as a working memory. For example, the volatile memory device 1230 may be a dynamic random access memory, such as DDR SDRAM, LPDDR SDRAM, GDDR SDRAM, RDRAM, etc. According to example embodiments, the volatile memory device 1230 may include a collision controller CLCON as described with reference to FIGS. 1 through 13. Using the collision controller CLCON, the volatile memory device 1230 may receive the active command during the refresh operation by controlling collision between the access operation and the refresh operation. The access operation may be initiated before the refresh operation is completed and the operation speed and the performance of the memory device and the memory system may be enhanced.

The nonvolatile memory device 1240 may store a boot image for booting the mobile system 1200. For example, the nonvolatile memory device 1240 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 1250 may include at least one input device, such as a keypad, a touch screen, etc., and at least one output device, such as a speaker, a display device, etc. The power supply 1260 may supply a power supply voltage to the mobile system 1200. In some embodiments, the mobile system 1200 may further include a camera image processor (CIS), and/or a storage device, such as a memory card, a solid state drive (SSD), a hard disk drive (HDD), a CD-ROM, etc.

In some embodiments, the mobile system 1200 and/or components of the mobile system 1200 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi-chip package (MCP), wafer-level fabricated package (WFP), wafer-level processed stack package (WSP), etc.

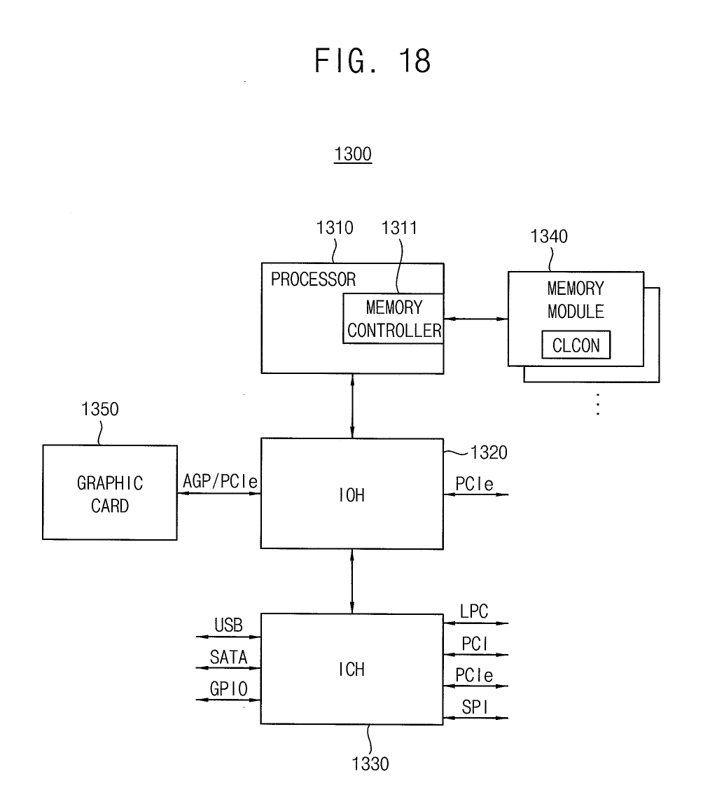

FIG. 18 is a block diagram illustrating a computing system according to example embodiments.

Referring to FIG. 18, a computing system 1300 includes a processor 1310, an input/output hub (IOH) 1320, an input/output controller hub (ICH) 1330, at least one memory module 1340, and a graphics card 1350. In some embodiments, the computing system 1300 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 1310 may perform various computing functions such as executing specific software for performing specific calculations or tasks. For example, the processor 1310 may be a microprocessor, a central process unit (CPU), a digital signal processor, or the like. In some embodiments, the processor 1310 may include a single core or multiple cores. For example, the processor 1310 may be a multi-core processor, such as a dual-core processor, a quad-core processor, a hexa-core processor, etc. Although FIG. 18 illustrates the computing system 1300 including one processor 1310, in some embodiments, the computing system 1300 may include a plurality of processors. The processor 1310 may include an internal or external cache memory.

The processor 1310 may include a memory controller 1311 for controlling operations of the memory module 1340. The memory controller 1311 included in the processor 1310 may be referred to as an integrated memory controller (IMC). A memory interface between the memory controller 1311 and the memory module 1340 may be implemented with a single channel including a plurality of signal lines, or may bay be implemented with multiple channels, to each of which at least one memory module 1340 may be coupled. In some embodiments, the memory controller 1311 may be located inside the input/output hub 1320, which may be referred to as memory controller hub (MCH).

The memory module 1340 may include at least one memory chip. The memory chip may include a collision controller CLCON as described with reference to FIGS. 1 through 13. Using the collision controller CLCON, memory module 1340 may receive the active command during the refresh operation by controlling collision between the access operation and the refresh operation. The access operation may be initiated before the refresh operation is completed and the operation speed and the performance of the memory device and the memory system may be enhanced.

The input/output hub 1320 may manage data transfer between processor 1310 and devices, such as the graphics card 1350. The input/output hub 1320 may be coupled to the processor 1310 via various interfaces. For example, the interface between the processor 1310 and the input/output hub 1320 may be a front side bus (FSB), a system bus, a HyperTransport, a lightning data transport (LDT), a QuickPath interconnect (QPI), a common system interface (CSI), etc. Although FIG. 18 illustrates the computing system 1300 including one input/output hub 1320, in some embodiments, the computing system 1300 may include a plurality of input/output hubs. The input/output hub 1320 may provide various interfaces with the devices. For example, the input/output hub 1320 may provide an accelerated graphics port (AGP) interface, a peripheral component interface-express (PCIe), a communications streaming architecture (CSA) interface, etc.

The graphic card 1350 may be coupled to the input/output hub 1320 via AGP or PCIe. The graphics card 1350 may control a display device (not shown) for displaying an image. The graphics card 1350 may include an internal processor for processing image data and an internal memory device. In some embodiments, the input/output hub 1320 may include an internal graphics device along with or instead of the graphics card 1350 outside the graphics card 1350. The graphics device included in the input/output hub 1320 may be referred to as integrated graphics. Further, the input/output hub 1320 including the internal memory controller and the internal graphics device may be referred to as a graphics and memory controller hub (GMCH).

The input/output controller hub 1330 may perform data buffering and interface arbitration to efficiently operate various system interfaces. The input/output controller hub 1330 may be coupled to the input/output hub 1320 via an internal bus, such as a direct media interface (DMI), a hub interface, an enterprise Southbridge interface (ESI), PCIe, etc. The input/output controller hub 1330 may provide various interfaces with peripheral devices. For example, the input/output controller hub 1330 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 1310, the input/output hub 1320 and the input/output controller hub 1330 may be implemented as separate chipsets or separate integrated units. In other embodiments, at least two of the processor 1310, the input/output hub 1320 and the input/output controller hub 1330 may be implemented as a single chipset. Also, while many features of the embodiments are disclosed as units, in other embodiments those features may be implemented as other forms of logic including but not limited to code-based operations performed by a processor.

As such, the memory device and the memory system including the memory device according to example embodiments may receive the active command during the refresh operation by controlling collision between the access operation and the refresh operation. The access operation may be initiated before the refresh operation is completed and the operation speed and the performance of the memory device and the memory system may be enhanced.

The present disclosure may be applied to arbitrary devices and systems including a memory device. For example, the present disclosure may be applied to systems such as be a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A memory device comprising:
a memory bank including a plurality of memory blocks;
a command control logic circuit configured to decode commands received from a memory controller to generate control signals, the command control logic circuit configured to receive an active command for an access operation during a refresh operation;
a row selection circuit configured to perform the access operation and the refresh operation with respect to the memory bank;
a refresh controller configured to control the refresh operation; and
a collision controller configured to generate a wait signal causing a delay of the access operation based on a result of a comparison of a row address associated with the access operation and a refresh address associated with the refresh operation.

2. The memory device of claim 1, wherein the command control logic circuit is configured to receive the active command before a refresh cycle time for completing the refresh operation has elapsed after a refresh command has been received.

3. The memory device of claim 1, wherein the command control logic circuit is configured to receive the active command during a self-refresh mode.

4. The memory device of claim 1, wherein the collision controller is configured to activate the wait signal when a memory block corresponding to the row address is equal to or adjacent to a memory block corresponding to the refresh address.

5. The memory device of claim 1, wherein the collision controller is configured to not activate the wait signal when a memory block corresponding to the row address is neither equal to nor adjacent to a memory block corresponding to the refresh address; and
wherein the row selection circuit is configured to simultaneously perform the access operation and the refresh operation when the wait signal is not activated.

6. The memory device of claim 5, wherein the row selection circuit is configured to delay the access operation by an activation time of the wait signal.

7. The memory device of claim 5, wherein the command control logic circuit is configured to receive the active command again after an activation time of the wait signal has elapsed.

8. The memory device of claim 1, wherein the collision controller includes:
an enable signal generator configured to generate an enable signal based on an internal signal indicating reception timing of the active command and a refresh done signal indicating completion of the refresh operation;
an address comparator configured to generate a comparison signal based on the enable signal, the row address and the refresh address; and
a wait signal generator configured to generate the wait signal based on the comparison signal and the refresh done signal.

9. The memory device of claim 8, wherein the enable signal generator is configured to activate the enable signal when the active command is received during the refresh operation, wherein the address comparator is enabled when the enable signal is activated.

10. The memory device of claim 8, wherein the wait signal generator is configured to activate the wait signal in response to the comparison signal and configured to deactivate the wait signal in response to the refresh done signal.

11. The memory device of claim 8, wherein the internal signal is an internal row address strobe signal indicating start timing of row access for enabling a row or a wordline corresponding to a row address.

12. The memory device of claim 8, wherein the refresh done signal has a first logic level during a refresh cycle time to indicate a start time point of the refresh operation and wherein the refresh done signal has a second logic level during the refresh cycle time to indicate an end time point of the refresh operation.

13. The memory device of claim 1, wherein the command control logic circuit is configured to determine whether to exit a self-refresh mode based on auto self-refresh exit information when the active command is received during the self-refresh mode.

14. The memory device of claim 13, wherein the auto self-refresh exit information is included in the active command received from the memory controller.

15. The memory device of claim 13, further comprising:
a mode register configured to store values for controlling an operation of the memory device,
wherein the auto self-refresh exit information is stored in the mode register.

16. The memory device of claim 13, wherein the command control logic circuit is configured finish the self-refresh mode in response to the active command when the auto self-refresh exit information has a first value, and the command control logic circuit is configured to maintain the self-refresh mode regardless of the active command when the auto self-refresh exit information has a second value.

17. A memory system comprising:
a memory device; and
a memory controller configured to control the memory device,
the memory device comprising:
a memory bank including a plurality of memory blocks;
a command control logic circuit configured to decode commands received from the memory controller to generate control signals, the command control logic circuit configured to receive an active command for an access operation during a refresh operation;
a row selection circuit configured to perform the access operation and the refresh operation with respect to the memory bank;
a refresh controller configured to control the refresh operation; and
a collision controller configured to generate a wait signal indicating collision between the access operation and the refresh operation based on a result of comparing a row address associated with the access operation and a counter address associated with the refresh operation.

18. A memory device comprising:
a memory bank including a plurality of memory blocks;
a logic circuit configured to decode commands received from a memory controller, the logic circuit configured to receive an active command for an access operation during a refresh operation;
a row selection circuit configured to perform the access operation and the refresh operation with respect to the memory bank;
a first controller configured to control the refresh operation; and
a second controller configured to compare a row address for the access operation and a counter address for the refresh operation and generate a comparison result, the second controller configured to activate a wait signal to delay the access operation when the comparison result indicates that a memory block corresponding to the row address is equal to or adjacent to a memory block corresponding to the counter address.

19. The memory device of claim 18, wherein the row selection circuit is configured to delay the access operation by an activation time of the wait signal.

20. The memory device of claim 18, wherein the second controller is configured to not activate the wait signal when the comparison result indicates that a memory block corresponding to the row address is neither equal to nor adjacent to a memory block corresponding to the counter address; and
wherein the row selection circuit is configured to simultaneously perform the access operation and the refresh operation in response to receipt of the active command when the wait signal is not activated.
